(19) United States
(12) Patent Application Publication
(10) Pub. No.: US 2013/0181116 A1
(43) Pub. Date: Jul. 18, 2013

(54) IMAGE PICKUP APPARATUS AND METHOD OF DRIVING THE SAME

(71) Applicant: CANON KABUSHIKI KAISHA, Tokyo (JP)

(72) Inventors: Takashi Matsuda, Yokohama-shi (JP); Toshiaki Ono, Ebina-shi (JP); Yuichiro Yamashita, Sendai-shi (JP)

(73) Assignee: CANON KABUSHIKI KAISHA, Tokyo (JP)

(21) Appl. No.: 13/738,863

(22) Filed: Jan. 10, 2013

(30) Foreign Application Priority Data
Jan. 18, 2012 (JP) 2012-008203

(51) Int. Cl. H01L 27/146

(52) U.S. Cl. CPC H01L 27/14601
USPC 250/208.1

(57) ABSTRACT

In an image pickup apparatus, a plurality of vertical signal lines are disposed in each pixel column. A pixel array includes pixels of first color and pixels of second color different from the first color. Two pixels of the first color are located at different row addresses and different column addresses. Signals from two pixels of the same color are processed simultaneously by a plurality of first column circuits.

### BACKGROUND OF THE INVENTION

1. Field of the Invention

The present invention relates to an image pickup apparatus, and more specifically, to a technique of reading out signals from pixels.

2. Description of the Related Art

To read out a signal from a pixel array at a high speed, it is known to dispose a plurality of vertical signal lines in a pixel column. Japanese Patent Laid-Open No. 2005-311821 discloses a technique in which pixels in even-numbered rows in each column are connected to one vertical signal line VL0 of two vertical signal lines, and pixels in odd-numbered rows are connected to the other vertical signal line VL1. The vertical signal line VL0 is connected to a reading circuit located in an area adjacent to a lower side of the pixel array, and the vertical signal line VL1 is connected to a reading circuit located in an area adjacent to an upper side of the pixel array.

The present inventors have found that in a configuration in which a plurality of vertical signal lines are disposed in each pixel column and signals are processed in parallel by column circuits disposed in areas adjacent to upper and lower sides of a pixel array, there is a possibility that signal crosstalk may occur between column circuits corresponding to adjacent pixel columns.

A discussion is given below on a case in which each column circuit includes an amplifier circuit. When this amplifier circuit is configured to have a high voltage gain such as 10 or higher, signal crosstalk may occur in the column circuit. When signals processed by adjacent column circuits are of the same or similar color, the crosstalk does not exert, in most cases, a significant influence on image quality unless the crosstalk is very great. However, crosstalk may exert an influence when pixel signals processed by adjacent column circuits are of different colors.

In view of the above, embodiments of the present invention are related to a configuration in which a plurality of vertical signal lines are disposed in each pixel column, and a column circuit is disposed for each vertical signal line.

### SUMMARY OF THE INVENTION

According to an embodiment, an image pickup apparatus includes a pixel array including a plurality of pixels arranged in a two-dimensional array, the pixels including a plurality of first pixels each configured to output a signal corresponding to light in a first wavelength range and a plurality of second pixels each configured to output a signal corresponding to light in a second wavelength range, a plurality of first column circuits disposed in a first peripheral region adjacent to the pixel array, a plurality of second column circuits disposed in a second peripheral region adjacent to the pixel array and opposing, across the pixel array, the first peripheral region in which the plurality of first column circuits are disposed, a plurality of vertical signal lines disposed such that two or more vertical signal lines are disposed in each pixel column, and a vertical scanning circuit configured to simultaneously select a plurality of pixel rows and output signals to the plurality of first column circuits and the plurality of second column circuits, wherein the plurality of first pixels simultaneously selected by the vertical scanning circuit are different in both row address and column address, and signals from the first pixels are processed in parallel by the plurality of first column circuits.

Further features of the present invention will become apparent from the following description of exemplary embodiments with reference to the attached drawings.

### BRIEF DESCRIPTION OF THE DRAWINGS

FIG. 1 is a block diagram illustrating a total configuration of an image pickup apparatus according to a first embodiment.

FIG. 2 is an equivalent circuit of a pixel according to the first embodiment.

FIG. 3 is a diagram illustrating driving pulses by which to drive the image pickup apparatus according to the first embodiment.

FIG. 4 is a diagram for use in explaining a manner in which noise occurs.

FIG. 5 is a block diagram illustrating a total configuration of an image pickup apparatus according to a second embodiment.

### DESCRIPTION OF THE EMBODIMENTS

According to an embodiment of the present invention, an image pickup apparatus is a color image pickup apparatus which includes a pixel array including a plurality of pixels arranged in a two-dimensional array. A plurality of vertical signal lines including a first vertical signal line and a second vertical signal line are disposed in each pixel column. Each first vertical signal line supplies a signal to a corresponding one of first column circuits disposed in a region (for example, in an upper area of a top view) adjacent to the pixel array. Each second vertical signal line supplies a signal to a corresponding one of second column circuits disposed in a region (for example, in a lower area of the top view) adjacent to the pixel array and opposing the region of the first column circuits via the pixel array. The image pickup apparatus includes a vertical scanning circuit thereby to simultaneously select a plurality of pixel rows and output signals to the plurality of first column circuits and the plurality of second column circuits via the plurality of vertical signal lines.

According to an embodiment of the present invention, the plurality of pixels arranged in the pixel array may include a plurality of first pixels each configured to output a signal corresponding to light in a first wavelength range and a plurality of second pixels each configured to output a signal corresponding to light in a second wavelength range different from the first wavelength range. Note that different wavelength ranges do not necessarily need to be absolutely different without having any overlap, but wavelength ranges may partially overlap each other. To realize such pixels, a color filter array may be disposed on the pixel array. Alternatively, photoelectric conversion units may be formed in a semiconductor substrate such that the depth of each photoelectric conversion unit as measured from a surface of the semiconductor substrate may be changed depending on the wavelength range.

Signals from a plurality of first pixels at different row addresses and different column addresses selected simultaneously by the vertical scanning circuit are processed in parallel by the plurality of first column circuits. In the parallel processing, it may be advantageous to perform all processes simultaneously, although part of the processes may be performed simultaneously. Note that a slight difference in processing timing due to, for example, a delay caused by wiring resistance or the like may be allowed in the simultaneous processing.

In the image pickup apparatus configured in the above-described manner, even when crosstalk occurs among signals processed by first column circuits, the crosstalk is limited to that among signals of the same color. This results in an improvement in image quality compared with that achieved by a configuration disclosed, for example, in Japanese Patent Laid-Open No. 2005-311821, in which signals are transmitted to upper or lower column circuits simply depending on whether signals are from even-numbered rows or odd-numbered rows.

Note that in any embodiment, pixel columns and pixel rows are defined simply for distinguishing between two directions in which pixels are arranged in the two-dimensional array. Therefore, the pixel rows and pixel columns may be replaced with each other in any embodiment.

### First Exemplary Embodiment

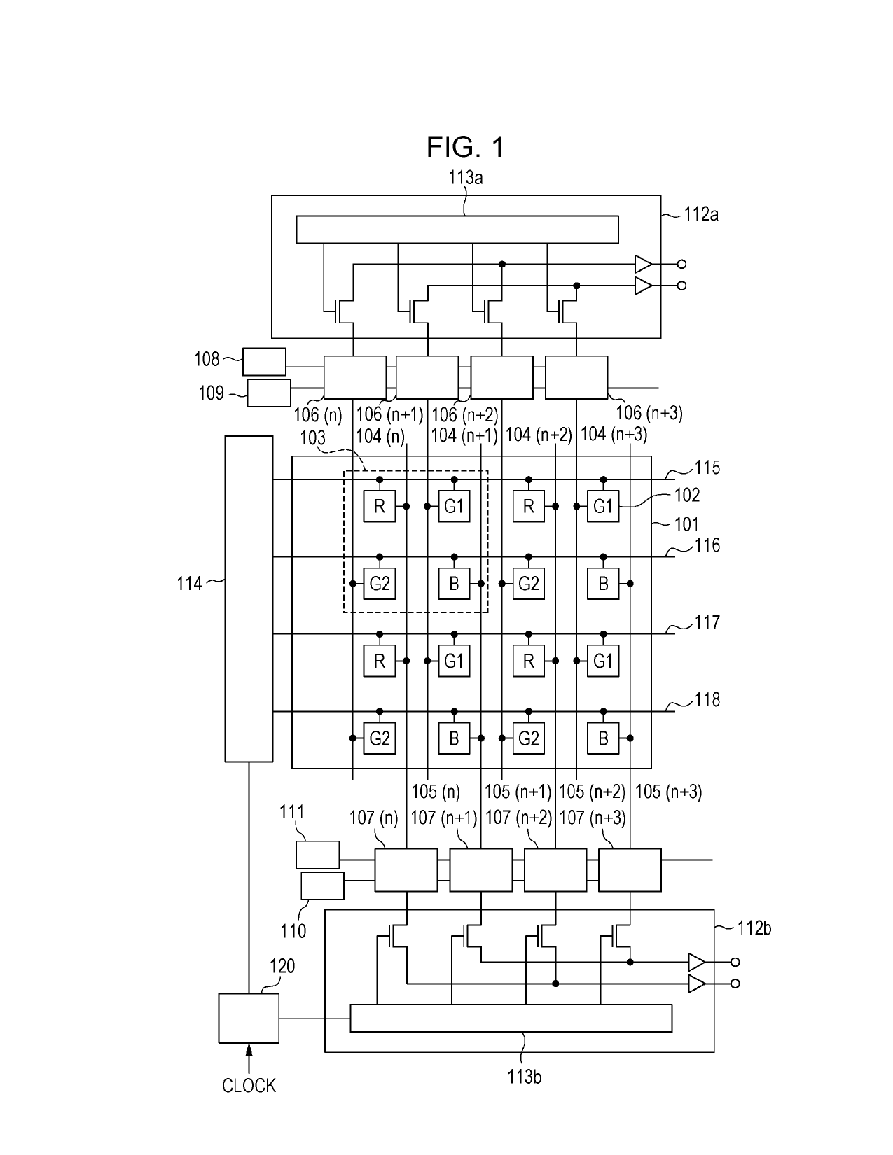

FIG. 1 is a block diagram illustrating a total configuration of an image pickup apparatus according to a first exemplary embodiment.

A plurality of pixels 102 are arranged in a two-dimensional array so as to form a pixel array region 101. In this example, a total of 16 pixels are arranged in a two-dimensional array including 4 rows and 4 columns. Note that the total number of pixels may be greater than that in this example. Each pixel has a color filter such that a photoelectric conversion is performed for light in a particular wavelength range. In the present embodiment, the color filter array used is of a Bayer pattern. Note that the color filter array is disposed so as to correspond to the pixel array. In FIG. 1, pixels denoted by R are red pixels, pixels denoted by G are green pixels, and pixels denoted by B are blue pixels, which are configured to perform photoelectric conversions on light in the respective specified wavelength ranges.

Each basic unit 103 includes 4 pixels arranged in a two-dimensional array including 2 rows and 2 columns, and a plurality of basic units 103 are arranged in a two-dimensional array. Each basic unit 103 may include one red pixel R, one blue pixel B, and two green pixels G1 and G2. In the basic unit 103, the red pixel R and the green pixel G1 are disposed adjacently in the same pixel row. That is, the red pixel R and green pixel G1 are equal in row address and different in column address. In each basic unit 103, the red pixel R and green pixel G2 are disposed adjacently in the same pixel column. That is, the red pixel R and the green pixel G2 are different in row address and equal in column address.

Furthermore, in each basic unit 103, the blue pixel B and the green pixel G2 are disposed adjacently in the same pixel row. That is, the blue pixel B and the green pixel G2 are equal in row address and different in column address. The blue pixel B and the green pixel G1 are disposed adjacently in the same pixel column. That is, the blue pixel B and the green pixel G1 are different in row address and equal in column address.

Furthermore, in each basic unit 103, the green pixels G1 and G2 are different in both row address and column address.

In the present embodiment, two vertical signal lines 104 and 105 are disposed in each pixel column. To denote a pixel column number, a suffix in parentheses is used. For example, a first vertical signal line 104(n) and a second vertical signal line 105(n) are first and second vertical signal lines disposed in an n-th column. First vertical signal lines 104(n) to 104(n+3) disposed in respective pixel columns transmit signals to a plurality of first column circuits 106 disposed in a region adjacent to an upper side of the pixel array 101. Second vertical signal lines 105(n) to 105(n+3) disposed in respective pixel columns transmit signals to a plurality of second column circuits 107 disposed in a region adjacent to a lower side of the pixel array 101.

A pulse supply unit 108 supplies a control pulse to the plurality of first column circuits 106 to control the operation thereof. Operations performed by each column circuit 106 include, for example, holding a signal received from one of the first vertical signal lines 104(n) to 104(n+3), amplifying the signal, removing noise, converting the signal from analog form into digital form, etc. All of these operations may be performed, or one or a combination of two or more operations may be performed.

An operation timing is controlled by a pulse provided by the pulse supply unit 108. The pulse from the pulse supply unit 108 is supplied to the plurality of first column circuits 106 such that the operation timing is substantially equal for the plurality of first column circuits 106. Note that the operation timing may not be perfectly equal but may be substantially equal for the first column circuits 106 because a propagation delay may occur due to resistance of warnings when pulses are transmitted via the wirings and the delay may be dependent on the location of the column circuits. By controlling the operation timing in the above-described manner, it becomes possible for the plurality of first column circuits 106 to process signals in parallel.

The plurality of first column circuits 106 may receive a voltage necessary for the operation of the plurality of first column circuits from a voltage supply unit 109. The voltage may have a single voltage value or may have a plurality of voltage values. In a typical case where a plurality of voltages are supplied, one voltage is a ground voltage, and the other voltage is a power supply voltage with a value of, for example, 3 V or 1.8 V.

The second column circuit 107 may operate in a similar manner to the first column circuit 106. A pulse supply unit 110 may have a similar function to that of the pulse supply unit 108 although pulses are supplied not to the plurality of first column circuits 106 but to the plurality of second column circuits 107. A voltage supply unit 111 may have a similar function to that of the voltage supply unit 109 although voltages are supplied to the plurality of second column circuits 107.

Signals output via the plurality of first column circuits 106 are supplied to a horizontal signal processing unit 112a. The horizontal signal processing unit 112a includes a horizontal scanning circuit 113a by which to output the signals processed by the plurality of column circuits 106 to horizontal signal lines sequentially or randomly or simultaneously. The horizontal scanning circuit 113a may be realized using a shift register, an address decoder, etc.

When the column circuits 106 each include an analog-to-digital conversion circuit, the horizontal signal lines functions as buses via which to transmit digital signals. In the present embodiment, two horizontal signal lines are disposed. Note that a greater number of horizontal signal lines may be disposed to increase the speed of reading out the signals.

The horizontal signal processing unit 112b and the horizontal scanning circuit 113b may have similar functions to those of the horizontal signal processing unit 112a and the horizontal scanning circuit 113a, although locations are different.

A vertical scanning circuit 114 supply a control pulse to each pixel row of the pixel array. A plurality of pixel rows may be selected simultaneously, and signals may be output to the plurality of first column circuits and the plurality of second column circuits via corresponding vertical signal lines. The vertical scanning circuit 114 may be realized using a shift register, an address decoder, etc., as with the horizontal scanning circuit 113. Driving lines 115 to 118 respectively supply driving pulses to corresponding pixel rows. Although only one line is drawn for each pixel row in FIG. 1, the number of lines may vary depending on the number of transistors included in each pixel to control by driving pulses. In a case where a plurality of driving lines are disposed in each pixel row, driving pulses with different waveforms are supplied to the respective driving lines.

A timing controller 120 supplies control pulses to the horizontal scanning circuit 113 and the vertical scanning circuit 114. The horizontal scanning circuit 113 and the vertical scanning circuit 114 may switch their driving mode in response to control signals supplied from the timing controller 120. For example, the driving modes may include a still image mode, a motion image mode, resolution modes depending on the number of pixels to read out, etc.

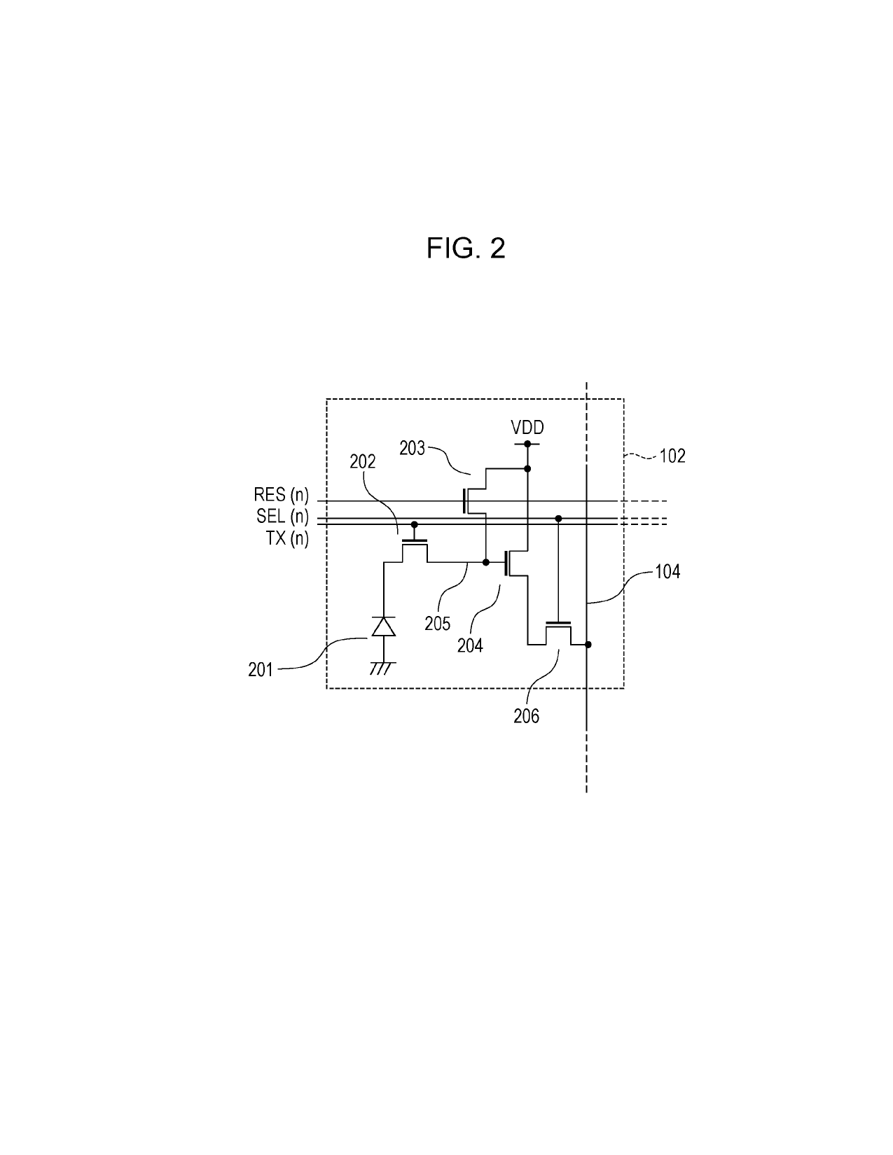

FIG. 2 illustrates an example of an equivalent circuit of one pixel 102. In the following explanation, by way of example, it is assumed that signal charges are provided by electrons and transistors in the pixel are of the N type, although signals charges may be provided by holes and transistors in the pixel may be of the P type.

A photodiode 201 is configured to convert incident light into electron-hole pairs. Note that the photodiode 201 may be replaced by another type of photoelectric conversion element. As for the photoelectric conversion element, it may be advantageous to employ an embedded-type photodiode. A transfer gate 202 transfers electrons generated in the photodiode 201 to a floating diffusion region 205. The floating diffusion region 205 may be formed by an N-type semiconductor region. A reset transistor 203 supplies a particular voltage to the floating diffusion region 205. A drain of the reset transistor 203 may be supplied with a power supply voltage VDD. The power supply voltage VDD is equal to, for example, 5 V, 3.3 V, etc. An amplifying transistor 204 functions to amplify a signal based on the electrons generated in the photodiode 201. A gate of the amplifying transistor 204 is electrically connected to the floating diffusion region 205. A drain of the amplifying transistor 204 may be supplied with the power supply voltage VDD as with the reset transistor 203. A selection transistor 206 may be disposed in an electrical path between a source of the amplifying transistor 204 and the vertical signal line 104.

A transfer control pulse is supplied to the transfer gate 202 via a transfer gate control line TX(n). A reset control pulse is supplied to a gate of the reset transistor 203 via a reset gate control line RES(n). A selection control pulse is supplied to a gate of the selection transistor 206 via a selection gate control line SEL(n). Note that n in parentheses in the selection gate control line SEL(n) indicates that this selection gate control line corresponds to the n-th pixel row.

The signal generated in the photodiode 201 is transferred to the floating diffusion region 205, then amplified by the amplifying transistor 204, and finally output to the vertical signal line 104 via the selection transistor 206. The amplifying transistor 204 may be configured so as to operate as a source follower. The selection transistor 206 may be disposed on a drain side of the amplifying transistor 204. Alternatively, a transistor dedicated to the selection operation may be omitted, and, instead, the voltage supplied to the floating diffusion region 205 from the reset transistor 203 may be controlled to switch a selection/non-selection state of the pixel. A plurality of photodiodes 201 may share part of transistors of the pixel such as the reset transistor 203, the amplifying transistor 204, etc.

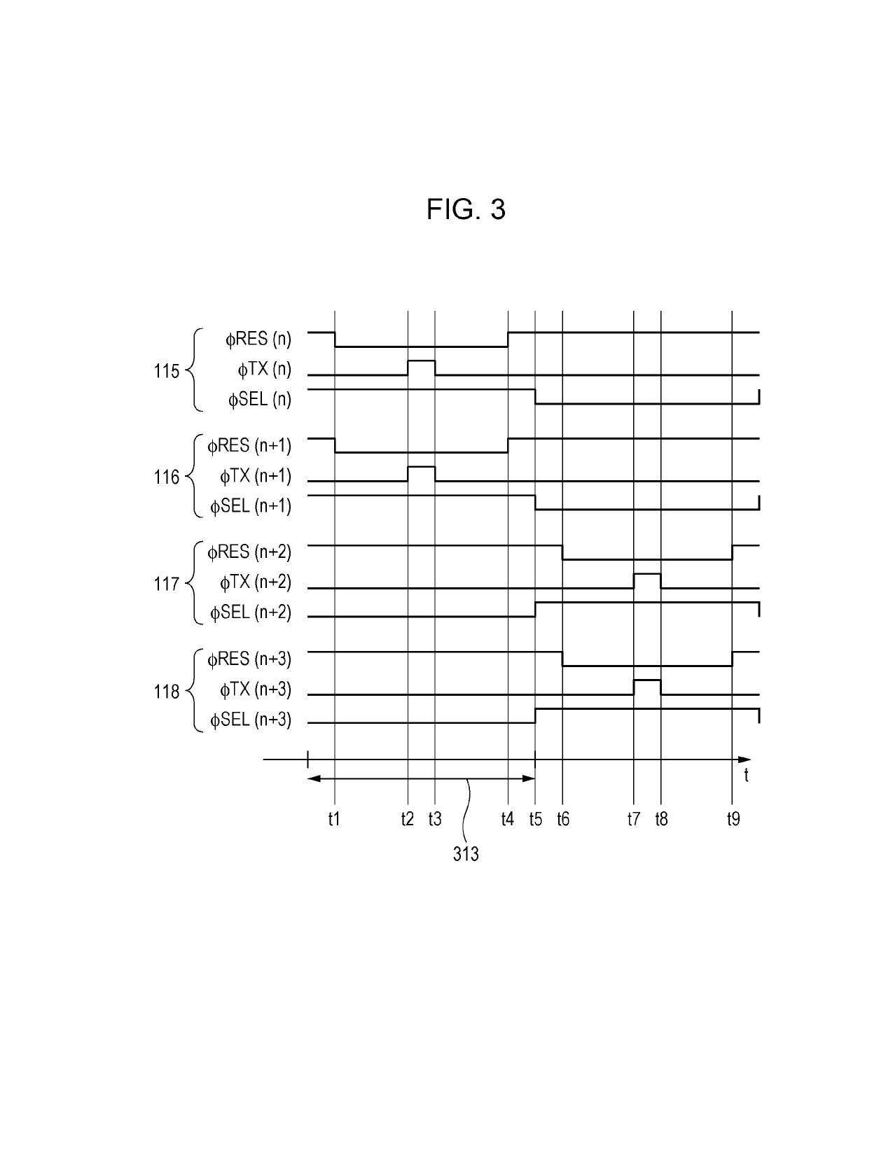

FIG. 3 illustrates driving pulses supplied to respective pixel rows. Note that it is assumed that each pixel is configured as illustrated in FIG. 2, and thus it is assumed that three driving lines are disposed in each pixel row. φRES illustrates a waveform of a driving pulse supplied to a gate of a reset transistor. φTX illustrates a waveform of a driving pulse supplied to a transfer gate. φSEL illustrates a waveform of a driving pulse supplied to a gate of a selection transistor. Each transistor is of the N type, and thus each transistor turns on when a supplied pule is at a high level. In the present embodiment, the vertical scanning circuit may select a plurality of pixel rows at the same time by simultaneously turning on selection transistors of the plurality of pixel rows by φSEL.

The driving lines 115 supply driving pulses to transistors of pixels in the n-th pixel row. The driving lines 116 supply driving pulses to transistors of pixels in the (n+1)th pixel row. The driving lines 117 supply driving pulses to transistors of pixels in the (n+2)th pixel row. The driving lines 118 supply driving pulses to transistors of pixels in the (n+3)th pixel row. Note that a suffix in parentheses following a symbol indicating a driving pulse is used to indicate a corresponding row number.

Before time t1, φRES(n) to φRES(n+3) are at the high level, and the particular voltage is supplied to the floating diffusion regions 205. φSEL(n) to φSEL(n+1) are maintained at the high level until time t5. In a period until time t5, signals of pixels in the n-th row and signal of pixels in the (n+1)th row may be output to the first and second vertical signal lines, respectively.

At time t1, φRES(n) and φRES(n+1) have a high-to-low level transition. In response, in a period to time t2, a noise signal in each pixel is sampled by the column circuit.

At time t2, φTX(n) and φTX(n+1) have a high-to-low level transition. In a period from t2 to t3, Charges in photodiodes in the pixels in the n-th row and (n+1)th row are transferred to corresponding floating diffusion regions. In a following period to time t4, optical signals are sampled by the column circuits.

At time t4, φRES(n) and φRES(n+1) have a low-to-high level transition.

At time t5, φSEL(n) and φSEL(n+1) have a high-to-low level transition, and φSEL(n+2) and φSEL(n+3) have a low-to-high level transition. By this time, the first vertical signal line and the second vertical signal line have become ready to read out signals from pixels in the (n+2)th row and the (n+3)th row.

In a following period from t6 to t9, an operation is performed on (n+2)th row and the (n+3)th row in a similar manner to the operation in the period t1 to t4.

As can be seen from FIG. 1, even for pixels in the same pixel row, signals from the pixels are output to the first vertical signal line or the second vertical signal line depending on the pixel columns of the pixels. For example, in the n-th column, a signal from the red pixel R in the n-th row may be output to the second vertical signal line 105(n) included in the group of second vertical signal lines. On the other hand, a signal from the green pixel G2 in the (n+1)th row and in the n-th column may be output to the first vertical signal line 104(n) included in the group of first vertical signal lines.

In the case of the (n+1)th column, a signal from the green pixel G1 in the n-th row may be output to the first vertical signal line 104(n+1) included in the group of first vertical signal lines, and a signal from the blue pixel B in the (n+1)th row and in the (n+1)th column may be output to the second vertical signal line 105(n+1) included in the group of second vertical signal lines. That is, signals from pixels in the n-th row is output such that signals are output to the second vertical signal line when the pixels are located in the n-th column while signals are output to the first vertical signal line when the pixels are located in the (n+1)th column. On the other hand, in the (n+1)th row, signals are output such that signals are output to the first vertical signal line when the pixels are located in the n-th column while signals are output to the second vertical signal line when the pixels are located in the (n+1)th column.

When the pixel array is configured in the above-described manner in terms of connections, if the operation is performed as illustrated in FIG. 3, the plurality of first column circuits 106 are capable of processing signals in parallel of the same color supplied from pixels which are different in both row address and column address. Thus, for example, although the green pixels G1 and G2 are located in different pixel rows, signals from these pixels are processed in the same period by adjacent column circuits. In the image pickup apparatus configured in the above-described manner, even when signal crosstalk occurs between adjacent column circuits 106, the adjacent column circuits 106 deal with the signals of the same color and thus no significant influence on image quality occurs unlike the configuration in which signals of different colors are processed by adjacent column circuits. In the present embodiment, the color filter array is of the Bayer pattern. Therefore, signals from a plurality of green pixels in the n-th row and (n+1)th row are processed in parallel by the plurality of first column circuits, and signals from a plurality of blue pixels in the n-th row and (n+1)th row are processed in parallel by the plurality of second column circuits.

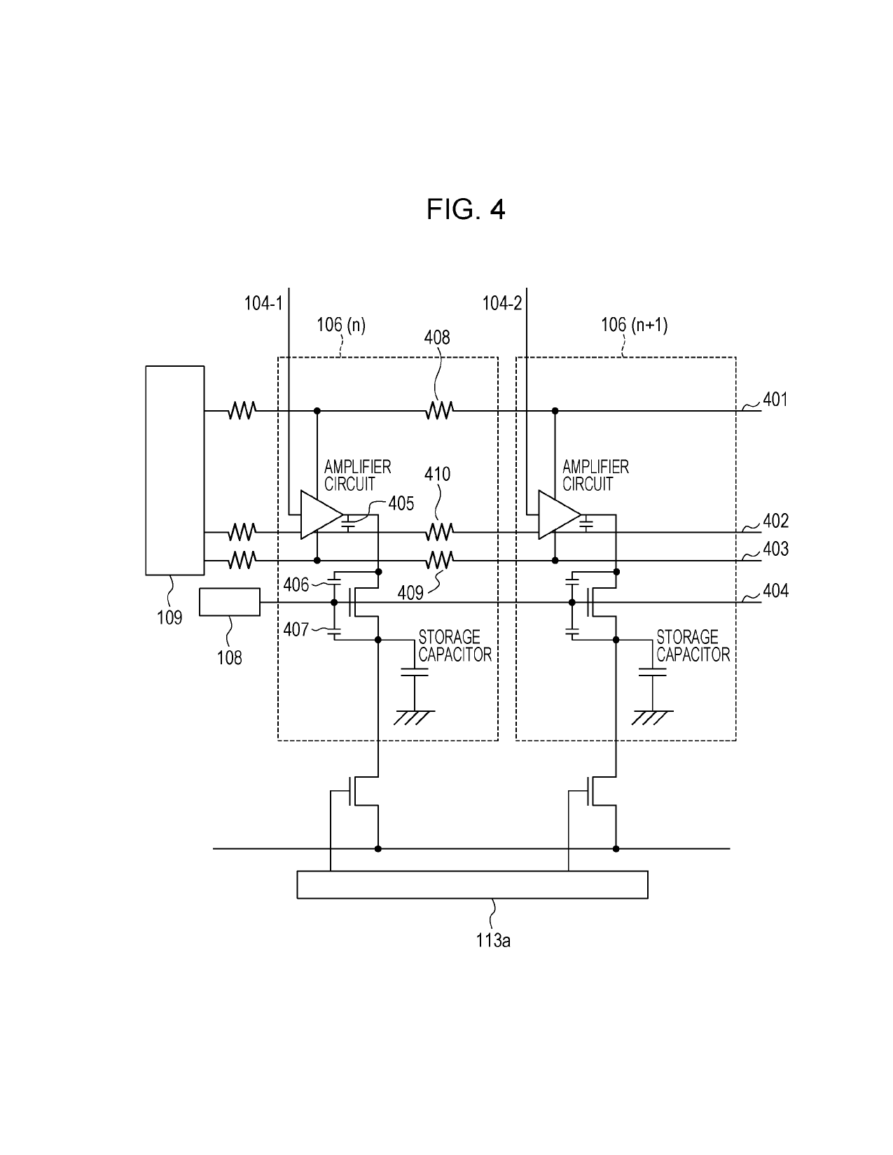

Next, referring to FIG. 4, a discussion is given below on a mechanism of generation of signal crosstalk between adjacent column circuits. In FIG. 4, parts having similar functions to those in FIGS. 1 to 3 are denoted by similar reference symbols, and a further detailed description thereof is omitted. Herein, when column circuits are said to be adjacent, column circuits are adjacent among the first column circuits 106 disposed in the upper region adjacent to the pixel array 101, or column circuits are adjacent among the second column circuits 107 disposed in the lower region adjacent to the pixel array 101.

The discussion is continued below taking, as an example, the group of first column circuits 106 which is one of groups of column circuits to which signals are supplied from n-th or (n+1)th pixel columns and which is located in the region adjacent to the upper side of the pixel array. Each first column circuit 106 is supplied with three voltages via three voltage supply lines from a voltage supply unit. These three voltage supply lines are referred to as a first voltage supply line 401, a second voltage supply line 402, and a third voltage supply line 403. For example, the voltage supplied via the first voltage supply line 401 is the power supply voltage, the voltage supplied via the second voltage supply line 402 is the ground voltage, and the voltage supplied via the third voltage supply line 403 is a voltage with a value between the power supply voltage and the ground voltage. For example, the third voltage is used as a reference voltage for the first column circuits 106.

The first voltage supply line 401 has wiring resistance 408 between the first column circuit 106(n) in the n-th column and the first column circuit 106(n+1) in the (n+1)th column. The second voltage supply line 402 has wiring resistance 410 between the first column circuit 106(n) and the first column circuit 106(n+1). Parasitic capacitance 405 occurs between an output node of the amplifier circuit of the first column circuit 106(n) and the third voltage supply line 403.

A pulse supply line 404 is disposed to transmit a pulse from the pulse supply unit 108 to the first column circuits 106(n) and 106(n+1). At a stage following the amplifier circuit of the first column circuit 106(n), a transistor functioning as a switch is disposed. This transistor is for controlling turning-on/off of an electrical connection between the amplifier circuit and a storage capacitor located at a following stage. The pulse supply unit 108 supplies a pulse to control this transistor. Parasitic capacitance 406 occurs between the source of this transistor and the pulse supply line 404 and parasitic capacitance 407 occurs between the drain of the transistor and the pulse supply line 404. The first to third voltage supply lines 401 to 403 and the pulse supply line 404 may be shared among the plurality of first column circuits.

In this configuration, for example, when light with a high intensity is incident on a pixel in the n-th column, the amplitude of an output signal from a corresponding amplifier circuit becomes large, which may cause a fluctuation in a potential on the first to third voltage supply lines 401 to 403 and the pulse supply line 404 via the parasitic capacitance 405 to 407. This influences a signal in an adjacent first column circuit. When a signal has a large amplitude, then to charge the large amplitude, a transient current flows through the first to third voltage supply lines 401 to 403, which results in a voltage drop across wiring resistance of these voltage supply lines 401 to 403. This causes the voltages to decrease from the specified values, which may also result in signal crosstalk.

In the configuration according to the present embodiment, even when the above-described signal crosstalk occurs, signals from the green pixels G1 and G2 are read out to the first column circuits 106 and processed, and thus crosstalk occurs between pixels of the same color. In most cases of crosstalk between signals of the same color, the difference in amplitude between adjacent pixels is small, and thus the influence on the image quality is small.

Signals output from the green pixels G1 and G2 play a great role in generating a luminance signal. Besides, the signals from the green pixels may have a great influence on image quality because human eyes are sensitive to spatial frequencies of green color. The signals of green pixels of such significant importance do not have crosstalk with signals of other colors, which results in an improvement in image quality.

Signals from the red pixels R and the blue pixels B are processed in parallel by the plurality of second column circuits 107 disposed in the region adjacent to the lower side of the pixel array 101. In this case, crosstalk between different colors may occur. However, improved image quality is achieved compared with that achieved by a conventional configuration (for example, the configuration disclosed in Japanese Patent Laid-Open No. 2005-311821) in which signals are supplied to upper or lower column circuit groups simply depending on whether signals are from even-numbered rows or odd-numbered rows. In the operations by the plurality of second column circuits 107, the processing timing may be shifted depending on the color of the signal.

In the present embodiment, as described above, a plurality of vertical signal lines are disposed in each pixel column, and signals of the same color from pixels located in different pixel rows and different pixel columns (i.e., at different row addresses and different column addresses) are processed by a plurality of column circuits. By configuring the image pickup apparatus in this manner, it becomes possible to reduce crosstalk between signals from pixels of different colors processed by column circuits. As a result, an improvement in image quality is achieved. Furthermore, green pixels are employed to provide signals of the same color. This is very effective in particular in forming a luminance signal.

### Second Exemplary Embodiment

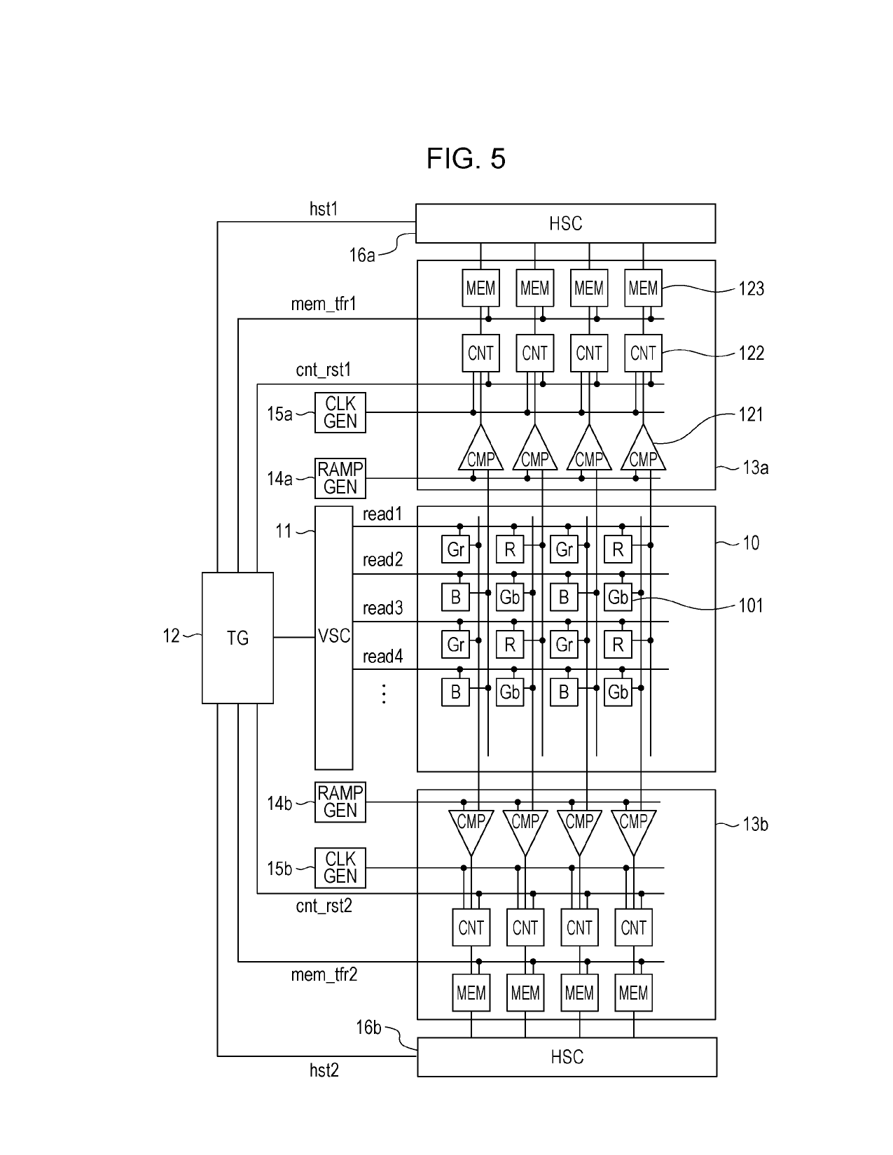

FIG. 5 illustrates an image pickup apparatus according to a second exemplary embodiment. The second exemplary embodiment is different from the first exemplary embodiment in that each column circuit includes an analog-to-digital (AD) converter. Signals from R pixels and B pixels are output to a first column circuit 13a and are subjected to an AD conversion with reference to a ramp signal generated by a ramp generator 14a.

A comparator 121 compares a signal output from a pixel 101 with the ramp signal from the ramp generator 14a. At an instance at which these two signals become equal, an comparator output inverts.

A counter 122 performs counting based on a clock generated by a counter clock generator 15a and stops the counting when the comparator output inverts.

Thus, a count value is held for each column such that the count value is proportional to a time elapsed until the comparator output inverts. That is, the count value is proportional to a corresponding pixel output.

When a memory 123 receives a pulse mem_tfr1, the memory 123 captures the count value held in the counter 122.

When a horizontal transfer circuit 16a receives a pulse hst1, the horizontal transfer circuit 16a sequentially scans the memories and outputs values captured by the respective memories.

When a pulse cnt_rst1 is input to the counter 122, the counter 122 is reset to an initial value and starts an AD conversion operation for a next row.

Signals from pixels Gr and pixels Gb, which are both green pixels, are output to a second column circuit 13b and are subjected to an AD conversion with reference to a ramp signal generated by a ramp generator 14b. The AD conversion is performed in a similar manner to that described above.

Because the analog signals output from pixels Gr and pixels Gb are converted into digital signals with reference to the same ramp signal, the analog signals are subjected to the AD conversion with very similar characteristic, which results in a reduction in errors of the luminance signal.

The present embodiment provides, in addition to the advantages provided by the first embodiment, a further advantage that the same reference voltage is used in the AC conversion, and thus an improvement in AD conversion accuracy is achieved.

### Third Exemplary Embodiment

Referring to FIG. 1, a configuration of an image pickup apparatus according to a third exemplary embodiment is described below. In this embodiment, the first and second column circuits each additionally include a plurality of signal holding units corresponding to the respective pixel columns. Signals from pixels in the n-th and (n+1)th rows are processed in parallel by the first and second column circuits 106 and 107, respectively. After the parallel processing is complete, resultant signals are transferred to first signal holding units corresponding to the respective columns. In a first period, the signals held in the first signal holding units are selected and output by a horizontal scanning circuit. In this first period, signals in the (n+2)th and (n+3)th rows are simultaneously selected by a vertical scanning circuit 104, and processed in parallel by the first column circuits 106 and the second column circuits 107, respectively. The configuration described above makes it possible to further increase the speed of reading out signals compared with those achieved by the first and second embodiments. In the configuration illustrated in FIG. 1, also for the (n+2)th and (n+3)th rows, signals from green pixels G1 and G2 are processed in parallel by the first column circuits 106, and signals from red and blue pixels R and B are process in parallel by the second column circuits 107.

The present invention has been described with reference to the embodiments. Note that many changes and modifications are possible without departing from the spirit of the present invention.

For example, although the Bayer pattern is employed in the embodiments described above, the manner of arranging pixels is not limited to the Bayer pattern as long as pixels which are similar in color and which are different in both row address and column address are simultaneously selected and processed in parallel by a plurality of column circuits. That is, if pixels of the same color existing in different pixel rows are selected simultaneously, the effects of the present invention are achieved regardless of the pattern of the CFA (Color Filter Array).

When the color of pixels which are read out into the column circuits on the same side is selected such that the color plays a great role in generating the luminance signal, a great effect of reducing the crosstalk is achieved, although any color may be selected as long as a reduction in crosstalk is achieved and thus an improvement in image quality is achieved.

In the present description, when the term “same color” is used, colors do not need to be the perfectly same, but the effects of the embodiments may be obtained if colors are substantially equal. More specifically, substantially equal colors may have a difference in spectral characteristic caused by interaction with a color filter of an adjacent pixel, a difference in spectral characteristic caused by a difference in thickness of a color filter, a difference in spectral characteristic caused by a color design, etc. However, the effects of the embodiments may be obtained as along as the spectral characteristic is substantially equal.

In the embodiments described above, by way of example, two vertical signal lines are disposed in each pixel column. Note that the effects of the embodiments may be achieved also when a greater number vertical signal lines are disposed. For example, when three vertical signal lines are disposed, the embodiments may be modifies such that green pixels located in three different pixel rows may be read out to column circuits located on the same side.

The effects of the embodiments may be achieved also in a case where the spectral characteristic of each of pixels arranged in a two-dimensional array is changed by selecting the depth of each pixel in a semiconductor layer to achieve color separation. The effects of the embodiments of the invention may be obtained by reading out and processing signals of three colors such that signals of one of the three colors are read out to column circuits located on the same side and processed thereby, which results in an avoidance of crosstalk with the other two colors. Therefore, the method of color separation is not important in achieving the effects of the embodiments.

In the embodiments described above, the details of the column circuits are not discussed. The embodiments are very effective in particular when a voltage amplification is performed by a very high gain of, for example, 10 or more. In some cases, crosstalk may occur at an input terminal of a victim circuit. In this case, if a voltage amplification is performed by a column signal processing circuit, the amplification may cause even small crosstalk to become very large crosstalk at an output terminal, which may result in a nonnegligible reduction in image quality.

As for the analog-to-digital conversion circuit, various types may be employed. More specifically, for example, it may be allowed to employ an analog-to-digital converter of a single slope type in which a triangle wave signal is used. Alternatively, it may be allowed to employ an analog-to-digital converter of a sequential comparison type, an integration type, a pipe line type, a cyclic type, etc., in all of which fixed reference voltages are used.

In the embodiments described above, the details of the horizontal signal processing circuit are not discussed. The configuration of the horizontal signal processing circuit does not make a contribution to the effects of the embodiments, and thus there is no specific restriction on the horizontal signal processing circuit. The horizontal signal processing circuit may be of a type using an analog line memory, a type in which a signal is converted into digital form and a result digital signal is transmitted, or other types, which may be properly selected depending on the signal type dealt with by the column signal processing circuit.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-008203, filed Jan. 18, 2012, which hereby incorporated by reference herein in its entirety.

What is claimed is:

1. An image pickup apparatus comprising:
a pixel array including a plurality of pixels arranged in a two-dimensional array, the pixels including a plurality of first pixels each configured to output a signal corresponding to light in a first wavelength range and a plurality of second pixels each configured to output a signal corresponding to light in a second wavelength range;
a plurality of first column circuits disposed in a first peripheral region adjacent to the pixel array;
a plurality of second column circuits disposed in a second peripheral region adjacent to the pixel array and opposing, across the pixel array, the first peripheral region in which the plurality of first column circuits are disposed;
a plurality of vertical signal lines disposed such that two or more vertical signal lines are disposed in each pixel column; and
a vertical scanning circuit configured to simultaneously select a plurality of pixel rows and output signals to the plurality of first column circuits and the plurality of second column circuits, wherein
the plurality of first pixels simultaneously selected by the vertical scanning circuit are different in both row address and column address, and signals from the first pixels are processed in parallel by the plurality of first column circuits.

2. The image pickup apparatus according to claim 1, wherein the first pixels are green pixels.

3. The image pickup apparatus according to claim 1, wherein the first and second column circuits include an amplifier circuit.

4. The image pickup apparatus according to claim 1, wherein the first and second column circuits include an analog-to-digital conversion circuit.

5. The image pickup apparatus according to claim 1, further comprising a color filter array disposed above the pixel array, wherein
the color filter array is configured according to a Bayer pattern.

6. The image pickup apparatus according to claim 5, wherein
signals from a plurality of green pixels disposed in an n-th row and an (n+1)th row are processed in parallel by the plurality of first column circuits, and
signals from a plurality of blue pixels and red pixels disposed in the n-th row and the (n+1)th row are processed in parallel by the plurality of second column circuits.

7. The image pickup apparatus according to claim 5, wherein
the plurality of first column circuits and the plurality of second column circuits each include a signal holding unit;
signals from a plurality of green pixels disposed in an n-th row and an (n+1)th row are processed in parallel by the plurality of first column circuits, and then held in signal holding units included in the first column circuits;
signals from a plurality of blue pixels and red pixels disposed in the n-th row and the (n+1)th row are processed in parallel by the plurality of second column circuits, and then held in signal holding units included in the second column circuits, and
during a period in which signals are held in the signal holding units, signals from pixels are processed such that signals from a plurality of green pixels disposed in an (n+2)th row and an (n+3)th row are processed in parallel by the plurality of first column circuits, and signals from a plurality of blue pixels and red pixels disposed in the (n+2)th row and the (n+3)th row are processed in parallel by the plurality of second column circuits.

8. A method of driving an image pickup apparatus, the image pickup apparatus including
a pixel array including a plurality of pixels arranged in a two-dimensional array, the pixels including a plurality of first pixels each configured to output a signal corresponding to light in a first wavelength range and a plurality of second pixels each configured to output a signal corresponding to light in a second wavelength range;
a plurality of first column circuits disposed in a first peripheral region adjacent to the pixel array;
a plurality of second column circuits disposed in a second peripheral region adjacent to the pixel array and opposing, across the pixel array, the first peripheral region in which the plurality of first column circuits are disposed; and
a plurality of vertical signal lines disposed such that two or more vertical signal lines are disposed in each pixel column,
the method comprising:
simultaneously selecting a plurality of pixel rows and outputting signals to the plurality of first column circuits and the plurality of second column circuits; and
processing in parallel, by the plurality of first column circuits, signals from a plurality of simultaneously selected first pixels different in both row address and column address.
